(19) United States
(12) Patent Application Publication
(10) Pub. No.: US 2015/0091561 A1
(43) Pub. Date: Apr. 2, 2015

(54) METHOD AND DEVICE FOR MAGNETIC RESONANCE IMAGING

(71) Applicant: Siemens Aktiengesellschaft, Muenchen (DE)

(72) Inventors: Guang Bao Dai, Shenzhen (CN); Jin Qiang He, Shenzhen (CN); Yan Tu Huang, Shenzhen (CN); Wen Ming Li, Shenzhen (CN); Hou Quan Lin, Shenzhen (CN); Tong Tong, Shenzhen (CN); JianMin Wang, Shenzhen (CN)

(73) Assignee: Siemens Aktiengesellschaft, Muenchen (DE)

(21) Appl. No.: 14/501,511

(22) Filed: Sep. 30, 2014

(30) Foreign Application Priority Data
Sep. 30, 2013 (CN) 201310464659.8

(51) Int. Cl. G01R 33/54

(52) U.S. Cl. CPC G01R 33/54
USPC 324/307

(57) ABSTRACT

A mode matrix processor of a magnetic resonance imaging system includes an input unit, an output unit, an operation unit, and a control unit, wherein the input unit is used for receiving a number of digital magnetic resonance signals; the operation unit is used for performing a linear combination operation on the plurality of digital magnetic resonance echo signals, to obtain at least one digital mode signal; the output unit is used for sending the at least one digital mode signal; and the control unit controls, according to the number of the digital magnetic resonance signals, the operation unit to perform the linear combination operation. The mode matrix processor of a magnetic resonance imaging system according to a specific embodiment of the present invention has desirable portability between different systems. The mode matrix processor of a magnetic resonance imaging system according to a specific embodiment of the present invention can improve the compatibility of coils between different systems.

### BACKGROUND OF THE INVENTION

1. Field of the Invention

The present invention relates to a magnetic resonance imaging system, and particularly to a mode matrix processor comprising a magnetic resonance imaging system.

2. Description of the Prior Art

Magnetic resonance imaging is a bio-magnetic nuclear spin imaging technology developed rapidly along with the development of computer technology, electronic circuit technology, and superconductor technology. In magnetic resonance imaging, human tissue is placed in a static magnetic field B₀, and then hydrogen nuclei within the human tissue are excited by a radio-frequency pulse with the same frequency as the precession frequency of the hydrogen nuclei, so as to cause resonance of the hydrogen nuclei and absorb energy. After the radio-frequency pulse is stopped, the hydrogen nuclei emit (radiate) a radio signal at a specific frequency and release the absorbed energy, which energy is detected (received) by a receiver, and the received signals are processed by a computer to obtain an image.

FIG. 1 is a block diagram of a magnetic resonance imaging system known in the prior art. As shown in FIG. 1, the magnetic resonance imaging system in the prior art has a scanning bed socket, a receiving coil channel selector, an analog receiver, a digital receiver, and an image data processor. A receiving coil is used for receiving a magnetic resonance echo signal, and an initial phase of the magnetic resonance echo signal entering a coil unit is a spatial phase of the magnetic resonance echo signal. The magnetic resonance signal received by the coil unit is transmitted to the scanning bed socket via the receiving coil. The magnetic resonance echo signal received by the scanning bed socket is transmitted to the receiving coil channel selector via a system cable. The magnetic resonance echo signal received by the receiving coil channel selector is transmitted to the analog receiver via channel mapping. The analog receiver performs analog-to-digital conversion on the received magnetic resonance echo signal, and transmits a first digital signal obtained through the analog-to-digital conversion to the digital receiver. The digital receiver converts the received first digital signal into a zero frequency band, thereby obtaining original data of image processing. Through certain Fourier transform and post-processing working, the image data processor forms an MRI image.

German patent DE 200310313004 discloses a mode matrix processor, that includes a phase shifter, a power splitter and a synthesizer implemented by hardware. This is a generally employed technology at present. FIG. 2 is a block diagram of a magnetic resonance imaging system of a plurality of coil units in the prior art. As shown in FIG. 2, in the magnetic resonance imaging system in the prior art, when the magnetic resonance imaging system receives magnetic resonance echo signals of a plurality of coil units regarding the same region, according to a specific phase relationship, a mode matrix processor directly processes N magnetic resonance echo signals from multiple coil units having a connection relationship that is correlated with the spatial locations thereof, and outputs mode signals with the same number. The concept of the mode matrix means generating a linear combination from input signals, and the linear combination may be mathematically described by a matrix, and a result of the linear combination is accordingly referred to as a “mode”. In the output mode signals, a first mode signal (a CP mode signal) contains most information about an image, and provides a maximum signal-to-noise ratio of an image center region. Other high-order mode signals (an LR mode signal, an ACP mode signal, etc.) further improve the signal-to-noise ratios of surrounding regions of the image. In the case of insufficient receiver receiving channels, only the first mode signal (the CP mode signal) may be provided for the magnetic resonance imaging system, i.e. the high-order mode (the LR mode signal, the ACP mode signal, etc.) is discarded while merely losing a little in terms of overall image signal-to-noise ratio as a cost.

In the magnetic resonance imaging system in the prior art, the mode matrix processor is implemented by hardware, that includes a phase shifter, a power splitter and a synthesizer. Meanwhile, as shown in FIG. 2, in the magnetic resonance imaging system in the prior art, the mode matrix processor directly processes magnetic resonance echo signals from multiple coil units to be combined in the magnetic resonance imaging system.

In the magnetic resonance imaging system in the prior art, the processing procedure of the mode matrix processor is a complex number operation, and an object processed thereby is a spatial phase of magnetic resonance echo signals from a plurality of coil units. In particular, the mode matrix processor comprises N input signals, and at least one output signal. Generally, the value of N is 2 or 3. For example, a mode matrix processor with N=3 may be (but is not limited to being) expressed as follows: L, R, and M respectively represent the magnetic resonance echo signals received by 3 side-by-side coil units, which are left, right and middle, and a first mode signal (a CP mode signal), a second mode signal (an LR mode signal), and a third mode signal (an ACP mode signal) respectively represent a first mode and two high-order modes provided as outputs by the mode matrix processor, wherein the mode matrix processor only the first mode signal as an output (the CP mode signal) generally:

$$C P = \frac{( L - R )}{2} + \frac{j * M}{\sqrt{2}}$$

$$L R = \frac{( L + R )}{\sqrt{2}}$$

$$A C P = \frac{( L - R )}{2} - \frac{j * M}{\sqrt{2}}$$

where the power splitter performs a subtraction operation; the synthesizer performs an addition operation; and the phase shifter performs a complex number operation.

There are various calculation manners for the first mode signal and high-order mode signal in the prior art, and at the same time, there are also various combinations of the number of input signals and the number of mode signals.

The development of electronic technology and magnetic resonance technology enables the costs of a high-speed sampling link to reduce and the number of coil channels to increase; therefore, there are more and more coil units for receiving magnetic resonance echo signals of the magnetic resonance imaging system. The mode matrix processor of the magnetic resonance imaging system in the prior art is not easily portable between different systems; however, applying the mode matrix processor to synthesize N magnetic resonance echo signals by means of a plurality of coil units is still an important manner in image processing.

### SUMMARY OF THE INVENTION

In order to preserve a synthesis function, of a mode matrix, for magnetic resonance echo signals of multiple coil units of a receiving coil, on the premise of keeping a mode matrix processing method, the embodiments of the present invention provide a mode matrix processor of a magnetic resonance imaging system, wherein the mode matrix processor has an input unit, an output unit, an operation unit, and a control unit, wherein the input unit is used for receiving a plurality of digital magnetic resonance signals; the operation unit is used for performing a linear combination operation on the plurality of digital magnetic resonance echo signals, to obtain at least one digital mode signal; the output unit is used for sending the at least one digital mode signal; and the control unit controls, according to the number of the digital magnetic resonance signals, the operation unit to perform the linear combination operation.

The operation unit has a synthesis module, a power splitter module, and a phase shift module, the synthesis module being used for performing an addition operation in the linear combination operation, the power splitter module being used for performing a subtraction operation in the linear combination operation, and the phase shift module being used for performing a phase operation in the linear combination operation; and the control unit controls, according to the number of the digital magnetic resonance signals, the synthesis module, the power splitter module, and the phase shift module to perform the corresponding linear combination operation.

The mode matrix processor is implemented by a programmable device.

The programmable device is an FPGA.

The mode matrix processor further has a memory, the memory being used for storing a phase difference generated in a magnetic resonance signal transmission process, and the control unit controls the phase shift module to perform, using the phase difference stored in the memory, a phase shift operation.

The mode matrix processor further has a detection unit, the detection unit being used for detecting the number of the digital magnetic resonance signals.

The input unit is further used for receiving the number of the digital magnetic resonance signals.

The control unit controls the output unit to output one or more of the at least one digital mode signal.

The mode matrix processor is connected between an analog receiver and a digital receiver of the magnetic resonance imaging system; or, the mode matrix processor is connected behind the digital receiver of the magnetic resonance imaging system.

The mode matrix processor of a magnetic resonance imaging system according to an embodiment of the present invention has desirable portability between different systems. The mode matrix processor of a magnetic resonance imaging system according to a specific embodiment of the present invention can improve compatibility of coils between different systems.

### BRIEF DESCRIPTION OF THE DRAWINGS

FIG. 1 is a block diagram of a magnetic resonance imaging system in the prior art.

FIG. 2 is a block diagram of a magnetic resonance imaging system with multiple coil units in the prior art.

FIG. 3 is a block diagram of a magnetic resonance imaging system according to an embodiment of the present invention.

FIG. 4 is a circuit diagram of a first calibration tool of a magnetic resonance imaging system according to an embodiment of the present invention.

FIG. 5 is a circuit diagram of a second calibration tool of a magnetic resonance imaging system according to an embodiment of the present invention.

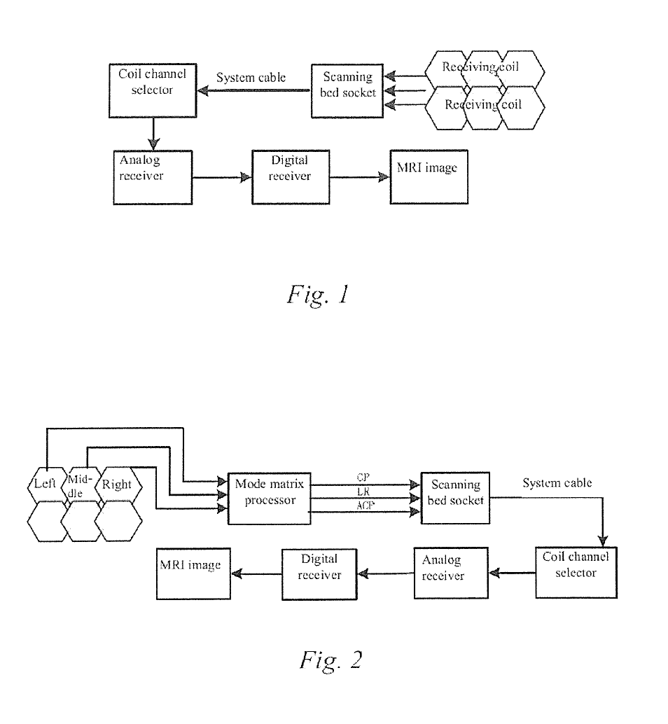

### DESCRIPTION OF THE PREFERRED EMBODIMENTS

In order to make the object, technical solutions and advantages of the present invention more apparent, the present invention will be further described in detail below in various embodiments.

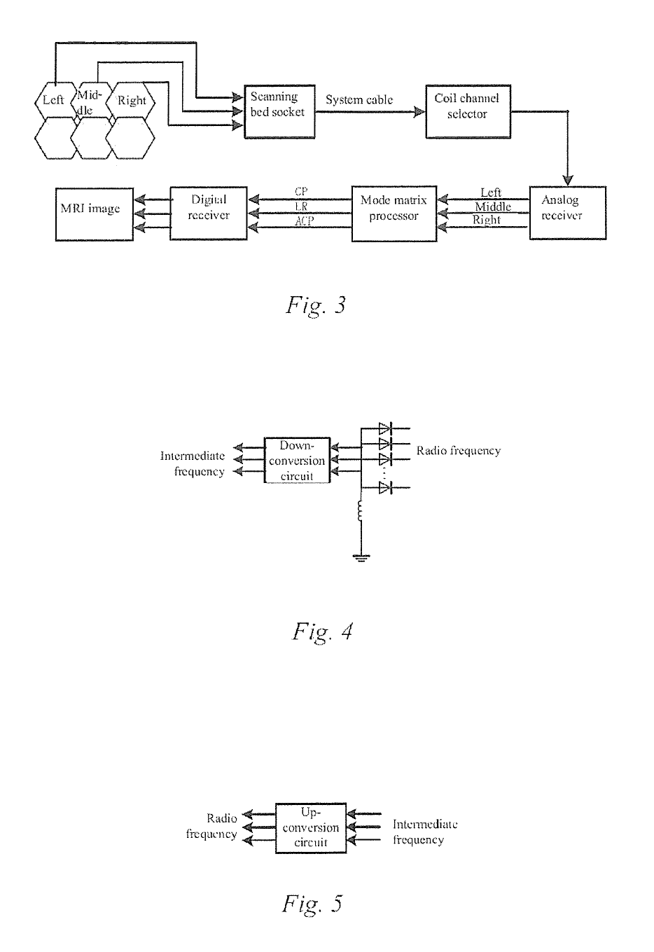

FIG. 3 is a block diagram of a magnetic resonance imaging system according to an embodiment of the present invention. As shown in FIG. 3, the magnetic resonance imaging system according to an embodiment of the present invention has a scanning bed socket, a receiving coil channel selector, an analog receiver, a mode matrix processor, a digital receiver, and an image data processor. In particular, a receiving coil is used for receiving N magnetic resonance echo signals from a plurality of coil units, and an initial phase of the N magnetic resonance echo signals entering the plurality of coil units is a spatial phase of the magnetic resonance echo signals; the magnetic resonance signals received by the coil units are transmitted from the scanning bed socket to the interior of the magnetic resonance imaging system via the receiving coil; the magnetic resonance echo signals received by the scanning bed socket are transmitted to the receiving coil channel selector via a system cable; the magnetic resonance echo signals received by the receiving coil channel selector are transmitted to the analog receiver via channel mapping; the analog receiver performs first sampling on the received N magnetic resonance echo signals and performs analog-to-digital conversion, and transmits a first sampling result of the analog-to-digital conversion to the mode matrix processor; the mode matrix processor transmits the N magnetic resonance echo signals to the digital receiver; and the digital receiver performs second sampling on the received mode signals, to obtain original data of image processing. Through certain Fourier transform and post-processing procedures, the image data processor forms an MRI image.

A mode matrix processor of a magnetic resonance imaging system according to an embodiment of the present invention. The mode matrix processor has an input unit, an output unit, an operation unit, and a control unit, wherein the input unit is used for receiving a number of digital magnetic resonance signals; the operation unit is used for performing a linear combination operation on the number of digital magnetic resonance echo signals, to obtain at least one digital mode signal; the output unit is used for sending the at least one digital mode signal; and the control unit controls, according to the number of the digital magnetic resonance signals, the operation unit to perform the linear combination operation.

As shown in FIG. 3, in the mode matrix processor of a magnetic resonance imaging system according to an embodiment of the present invention, when the magnetic resonance imaging system receives magnetic resonance echo signals from multiple coil units regarding the same region, according to a specific phase relationship, a mode matrix processor directly processes N magnetic resonance echo signals from multiple coil units having a connection relationship over spatial locations, and emits at least one mode signal as an output.

In particular, the concept of mode describes sensitivity distribution in an antenna field related to one or more antennas of an MR device and as a spatial function. The sensitivity distribution of a local antenna determines a signal-to-noise ratio in a shooting region. Accordingly, it is likewise the same regarding the sensitivity distribution of one mode, and the sensitivity distribution, for example, is also related to a shooting region of the local antenna which contributes to linear combination.

Each mode has a corresponding analog output signal, and the signals may serve as MR echo signals to be further processed as an MR photo. The concept of “linear combination of MR echo signals” comprises constituting the sum of a plurality of MR echo signals, wherein each MR echo signal may be phase-shifted and weighted in the sum. In this way, a 180-degree phase shift of the sum of two signals, for example, corresponds to a difference signal of the two signals. In an extreme condition of linear combination, a weighting of zero may be applied to all the signals except for one signal in linear combination, such that a generated mode corresponds to the MR echo signals, and if necessary, the signals are further phase-shifted. In a normal condition, a mutual linear operation is at least performed on two MR echo signals.

In an output mode signal, a primary (first) mode signal (a CP mode signal) corresponds to first optimal sensitivity distribution of a plurality of coil units with respect to a target region in a detection space in the magnetic resonance imaging system, and thus the primary mode signal contains most information about an image of the target region, and provides a maximum signal-to-noise ratio of an image center region; and other high-order (secondary) mode signals (an LR mode signal, an ACP mode signal, etc.) further improve the signal-to-noise ratios of surrounding regions of the image. In the case of insufficient receiver receiving channels, only the primary (first) mode signal (the CP mode signal) may be provided for the magnetic resonance imaging system, i.e. the secondary (high-order) mode (the LR mode signal, the ACP mode signal, etc.) is discarded with merely losing a little of the overall image signal-to-noise ratio as a cost.

The constitution of the primary mode is preferably implemented with an improved, i.e. an optimized sensitivity compared with the sensitivity of the local antenna. The primary mode may be understood as a basic mode, which may be processed as an MR photo, and improvement is represented by comparing itself with MR photos obtained from respective independent MR signals. Such an improvement especially occurs to a certain target region of the detection space, and in the target region, the image quality, such as the signal-to-noise ratio, is improved, wherein the sensitivity is optimized regarding, for example, nuclear spin signals of circular polarization.

On the contrary, the constitution of the secondary mode is preferably implemented in this way so as to maintain spatial information existing due to different spatial settings of the local antenna with respect to the detection space. Accordingly, the secondary mode also has sensitivity distribution, which is different from the first kind in a phase encoding direction of the MR echo signals. For example, the signal-to-noise ratio of the secondary mode is improved in regions other than the first target region. The phase encoding direction, for example, when the primary mode and the secondary mode are used for performing PAT, is superposed with the direction of the local antenna arrangement.

A first advantage used for a mode method is to use a primary mode from MR echo signals of the local antenna, wherein the primary mode has an improved sensitivity in the first target region. As a second advantage, a second mode (secondary mode) is additionally obtained, wherein the mode contains complementary information and may be combined with the primary mode, for example, used for PAT.

Another advantage used for a mode method is that, when the mode is processed as an MR photo, on one hand, the MR photo with an optimized sensitivity may be received only via an input channel, but there are also other input channels able to be used, which may introduce other modes, e.g. the secondary mode, into imaging. This enables, for example, that PAT may be performed using the primary mode and the secondary mode. The advantage also lies in that, in the case of using at least two local antennas, information content about all the MR echo signals may be reallocated to the primary and secondary modes. Forming represents a mode of a spatial encoding field function in layered settings. This may, for example, be performed for the sensitivity distribution of a single mode or for two modes used for PAT. In a preferred condition, reallocating a certain number of MR signals to the same number of modes may transfer all the information.

The operation unit of a mode matrix processor of a magnetic resonance imaging system according to a specific embodiment of the present invention is used for performing a linear combination operation on the multiple digital magnetic resonance echo signals, to obtain at least one digital mode signal; the output unit is used for sending the at least one digital mode signal; and the control unit controls, according to the number of the digital magnetic resonance signals, the operation unit to perform the linear combination operation.

In particular, the processing procedure of the mode matrix processor of the magnetic resonance imaging system according to a specific embodiment of the present invention is a linear combination operation, and objects processed thereby are magnetic resonance echo signals from a plurality of coil units. In particular, the mode matrix processor comprises N input signals, and N output signals. Generally, the value of N is 2 or 3. For example, a mode matrix processor with N=3 may be expressed as follows: L, R, and M respectively represent the digitalized magnetic resonance echo signals received by 3 parallel analog receivers, which are left, right and middle, and a first (primary) mode signal (a CP mode signal), a second mode signal (an LR mode signal), and a third mode signal (an ACP mode signal) respectively represent a primary (first) mode and two secondary (high-order) modes output by the mode matrix processor, wherein the mode processing matrix processor only outputs the primary (first) mode signal (the CP mode signal) generally:

$$C P = \frac{( L - R )}{2} + \frac{j * M}{\sqrt{2}}$$

$$L R = \frac{( L + R )}{\sqrt{2}}$$

$$A C P = \frac{( L - R )}{2} - \frac{j * M}{\sqrt{2}}$$

and the mode matrix processor of the magnetic resonance imaging system according to a specific embodiment of the present invention completes the calculation of the mode signals above by means of a programmable device, e.g. an FPGA, a PAL, a GAL, a CPLD, etc.

The operation unit has a synthesis module, a power splitter module, and a phase shift module, the synthesis module being used for performing an addition operation in the linear combination operation, the power splitter module being used for performing a subtraction operation in the linear combination operation, and the phase shift module being used for performing a phase operation in the linear combination operation; and the control unit controls, according to the number of the digital magnetic resonance signals, the synthesis module, the power splitter module, and the phase shift module to perform the corresponding linear combination operation. In the mode matrix processor of the magnetic resonance imaging system according to a specific embodiment of the present invention, with respect to different numbers of digital magnetic resonance echo signals, there are various primary (first) mode signal and secondary (high-order) mode signal calculation manners in the prior art, and at the same time, there are also various combinations of the number of output mode signals. Therefore, the operation unit comprises various different operation modules to perform the linear combination operation.

The mode matrix processor of the magnetic resonance imaging system according to an embodiment of the present invention further comprises a detection unit, the detection unit being used for detecting the number of the digital magnetic resonance signals. Alternatively, the input unit of the magnetic resonance imaging system according to an embodiment of the present invention is further used for receiving the number of the digital magnetic resonance signals.

The mode matrix processor of the magnetic resonance imaging system according to an embodiment of the present invention further has a memory, the memory being used for storing a phase difference generated in a magnetic resonance signal transmission process, and the control unit controls the phase shift module to perform, using the phase difference stored in the memory, a phase shift operation.

Meanwhile, as shown in FIG. 3, the mode matrix processor of the magnetic resonance imaging system according to an embodiment of the present invention processes a first sampling result of analog-to-digital conversion, i.e. an analog-to-digital conversion result, from an analog receiver. Therefore, since the phase delays of a plurality of coil units from receiving the magnetic resonance echo signals to completing analog receiver sampling are different, the different phase differences (delays) need to be calibrated, and the magnetic resonance echo signals above pass through a receiving coil and the magnetic resonance imaging system, and thus the phase differences (delays) above may be divided into: 1) a coil phase difference (external delay), i.e. a phase difference generated when the magnetic resonance echo signals pass through the receiving coil, and 2) a system phase difference (internal delay), i.e. a phase difference generated when the magnetic resonance echo signals pass through the magnetic resonance imaging system. In order to calibrate the phase differences above, the mode matrix processor of the magnetic resonance imaging system according to an embodiment of the present invention stores a coil phase difference and a system phase difference. The coil phase difference and the system phase difference may be measured in advance, and then the measured values are stored in the mode matrix processor of the magnetic resonance imaging system according to an embodiment of the present invention; meanwhile, the measured values above are measured again and updated periodically so as to guarantee the accuracy thereof.

There are various ways to measure the coil phase difference and the system phase difference. FIG. 4 is a circuit diagram of a first calibration tool of a magnetic resonance imaging system according to a specific embodiment of the present invention. FIG. 5 is a circuit diagram of a second calibration tool of a magnetic resonance imaging system according to a specific embodiment of the present invention. As shown in FIG. 4, the first calibration tool is used for measuring the coil phase difference, wherein the first calibration tool is jointly used with the magnetic resonance imaging system; and as shown in FIG. 5, the second calibration tool is used for measuring the system phase difference, wherein the second calibration tool is jointly used with the receiving coil, and the first calibration tool and the second calibration tool may be jointly used.

In particular, as shown in FIG. 4, the first calibration tool comprises a down-conversion circuit of an analog receiving coil, and when it is used, a receiving channel is gated by controlling an on/off matrix. The first calibration tool is jointly used with the magnetic resonance imaging system, thereby measuring and obtaining the sum of the phase difference of the first calibration tool and the system phase difference (a first phase difference sum) by means of a vector network analyzer.

As shown in FIG. 5, the second calibration tool comprises an up-conversion circuit opposite to the down-conversion circuit of the receiving coil. When it is used, the second calibration tool is jointly used with the receiving coil, thereby measuring and obtaining the sum of the phase difference of the second calibration tool and the receiving coil phase difference (a second phase difference sum) by means of the vector network analyzer.

Then, the first calibration tool is jointly used with the second calibration tool, thereby measuring the sum of the phase differences of the first calibration tool and the second calibration tool (a third phase difference sum) by means of the vector network analyzer.

The sum of the coil phase difference and the system phase difference=the first phase difference sum+the second phase difference sum−the third phase difference sum. The sum of the coil phase difference and the system phase difference is stored in the mode matrix processor of the magnetic resonance imaging system according to a specific embodiment of the present invention.

The mode matrix processor of the magnetic resonance imaging system according to an embodiment of the present invention may achieve mode matrix processing by means of external calibration on the basis of not modifying the hardware composition and the existing receiving coil design of the magnetic resonance imaging system, thus having desirable portability between different systems. The generation of mode signals of adjacent coil units is accomplished by means of digital processing, without the need for a hardware phase shifter and a synthesizer. The same receiving coil may be used in different systems in cooperation with different calibration parameters and different synthetic modes, and flexibly adjust coil units needing to be synthesized. The mode matrix processor of a magnetic resonance imaging system according to a specific embodiment of the present invention can improve compatibility of coils between different systems.

The mode matrix processor of a magnetic resonance imaging system according to an embodiment of the present invention is connected to the rear end of an analog receiver of the magnetic resonance imaging system and the front end of a digital receiver, and the mode matrix processor of the magnetic resonance imaging system according to an embodiment of the present invention may also be connected to the rear end of the digital receiver, thereby receiving N digital magnetic resonance echo signals from the digital receiver and sending at least one digital mode signal to an image digital processor. However, since the mode matrix processor of a magnetic resonance imaging system according to an embodiment of the present invention is connected to the rear end of an analog receiver of the magnetic resonance imaging system and the front end of a digital receiver, if only a first mode signal is emitted as an output from the mode matrix processor, then only one data line is needed for outputting the first mode signal; therefore, with respect to the fact that the mode matrix processor is connected to the rear end of the digital receiver, the system structure may be simplified and system wiring may be saved.

Although modifications and changes may be suggested by those skilled in the art, it is the intention of the inventors to embody within the patent warranted hereon all changes and modifications as reasonably and properly come within the scope of their contribution to the art.

We claim as our invention:

1. A mode matrix processor of a magnetic resonance imaging system, wherein the mode matrix processor comprises an input unit, an output unit, an operation unit, and a control unit, wherein the input unit is used for receiving a plurality of digital magnetic resonance signals; the operation unit is used for performing a linear combination operation on the plurality of digital magnetic resonance echo signals, to obtain at least one digital mode signal; the output unit is used for sending the digital mode signal; and the control unit controls, according to the number of the digital magnetic resonance signals, the operation unit to perform the linear combination operation.

2. The mode matrix processor as claimed in claim 1, characterized in that the operation unit comprises a synthesis module, a power splitter module, and a phase shift module, the synthesis module being used for performing an addition operation in the linear combination operation, the power splitter module being used for performing a subtraction operation in the linear combination operation, and the phase shift module being used for performing a phase operation in the linear combination operation; and the control unit controls, according to the number of the digital magnetic resonance signals, the synthesis module, the power splitter module, and the phase shift module to perform the corresponding linear combination operation.

3. The mode matrix processor as claimed in claim 1, characterized in that the mode matrix processor is implemented by a programmable device.

4. The mode matrix processor as claimed in claim 3, characterized in that the programmable device is an FPGA.

5. The mode matrix processor as claimed in claim 2, characterized in that the mode matrix processor further comprises a memory, the memory being used for storing a phase difference generated in a magnetic resonance signal transmission process, and the control unit controls the phase shift module to perform, using the phase difference stored in the memory, a phase shift operation.

6. The mode matrix processor as claimed in claim 1, characterized in that the mode matrix processor further comprises a detection unit, the detection unit being used for detecting the number of the digital magnetic resonance signals.

7. The mode matrix processor as claimed in claim 1, characterized in that the input unit is further used for receiving the number of the digital magnetic resonance signals.

8. The mode matrix processor as claimed in claim 1, characterized in that the control unit controls the output unit to output one or more of the digital mode signals.

9. A magnetic resonance imaging system comprising:
a magnetic resonance data acquisition unit operable to generate a plurality of digital magnetic resonance signals; and
a mode matrix processor comprising an input unit, an output unit, an operation unit, and a control unit, wherein the input unit for receiving said plurality of digital magnetic resonance signals; the operation unit is used for performing a linear combination operation on the plurality of digital magnetic resonance echo signals, to obtain at least one digital mode signal; the output unit is used for sending the digital mode signal; and the control unit controls, according to the number of the digital magnetic resonance signals, the operation unit to perform the linear combination operation.

10. A magnetic resonance imaging system as claimed in claim 9 wherein said magnetic resonance data acquisition unit comprises an analog receiver and a digital receiver, and wherein said mode matrix processor is connected between said analog receiver and said digital receiver.

11. A magnetic resonance imaging system as claimed in claim 9 wherein said magnetic resonance data acquisition unit comprises a digital receiver, and wherein said mode matrix processor is connected following said digital receiver.
